(19) United States
(12) Patent Application Publication
(10) Pub. No.: US 2013/0294041 A1
(43) Pub. Date: Nov. 7, 2013

(54) UICC ENCAPSULATED IN PRINTED CIRCUIT BOARD OF WIRELESS TERMINAL

(71) Applicant: SIERRA WIRELESS, INC., Richmond (CA)

(72) Inventor: Ashish SYAL, Vancouver (CA)

(73) Assignee: Sierra Wireless, Inc., Richmond (CA)

(21) Appl. No.: 13/886,431

(22) Filed: May 3, 2013

Related U.S. Application Data
(60) Provisional application No. 61/642,963, filed on May 4, 2012.

(51) Int. Cl. H05K 1/18

(52) U.S. Cl. CPC H05K 1/185
USPC 361/764

(57) ABSTRACT

A multilayer circuit board of a wireless terminal, a circuit assembly comprising the circuit board and a wireless terminal comprising the circuit assembly are provided. The wireless terminal is of a type which utilizes a UICC. The multilayer circuit board is configured to accommodate a UICC encapsulated within one or more interior layers of the multilayer circuit board, for example as a semiconductor die. The multilayer circuit board is further configured to accommodate one or more additional components integral to functionality of the wireless terminal, optionally also embedded within the circuit board. Integration of components into the interior layers may facilitate theft deterrence and/or tamper resistance. A physical programming interface to the encapsulated UICC may be rendered inaccessible after initial programming.

### BACKGROUND OF THE INVENTION

1. Field of the Invention

The present technology pertains in general to radio communication using terminals comprising Universal Integrated Circuit Card (UICC), Subscriber Identity Module (SIM) or the like.

2. Description of the Related Art

Conventionally, a UICC is an external and removable element in relation to the communication terminal with which it is associated. This is because its aim is to identify a “subscriber” who may decide to change terminals without wishing to change his identifier associated with the UICC. The latter is therefore arranged in a housing provided in the communication device.

UICCs contain valuable information usable for accessing wireless networks. As such, it is undesirable that a UICC or similar identity module should be lost or stolen. UICC theft can be regarded as a type of identity theft. Similarly, wireless terminals are valuable technology, and it is undesirable that a wireless terminal should be stolen, and its UICC removed and replaced in order to repurpose the wireless terminal or phone to make use of its subscription. This is a particular concern for unattended wireless terminals, such as Machine-to-Machine (M2M) terminals.

Measures have been proposed to more securely associate a SIM with its wireless terminal. For example, U.S. Pat. No. 8,131,318 discloses welding a SIM card to a radio communication device. However, in some cases a greater measure of security may be desired.

Therefore, there is a need for a wireless terminal and components thereof which associate a UICC with a wireless terminal more securely than solutions proposed in the prior art.

This background information is provided for the purpose of making known information believed by the applicant to be of possible relevance to the present technology. No admission is necessarily intended, nor should be construed, that any of the preceding information constitutes prior art against the present technology.

### SUMMARY OF THE INVENTION

An object of the present technology is to provide a UICC encapsulated in printed circuit board of a wireless terminal. In accordance with an aspect of the present technology, there is provided a multilayer circuit board of a wireless terminal, the wireless terminal utilizing a UICC, the multilayer circuit board comprising one or more interior layers and configured to accommodate: a UICC encapsulated within at least one of the one or more interior layers of the multilayer circuit board; and one or more additional components integral to functionality of the wireless terminal.

In accordance with another aspect of the present technology, there is provided a circuit assembly of a wireless terminal utilizing a UICC, the circuit assembly comprising a multilayer circuit board, the multilayer circuit board comprising one or more interior layers and configured to accommodate: a UICC encapsulated within at least one of the one or more interior layers of the multilayer circuit board; and one or more additional components integral to functionality of the wireless terminal, the circuit assembly further comprising the UICC and the additional components operatively coupled to the multilayer circuit board.

In accordance with another aspect of the present technology, there is provided a wireless terminal comprising a multilayer circuit board, the multilayer circuit board comprising one or more interior layers and configured to accommodate: a UICC encapsulated within at least one of the one or more interior layers of the multilayer circuit board; and one or more additional components integral to functionality of the wireless terminal.

In accordance with another aspect of the present technology, there is provided a method of manufacturing a circuit assembly comprising a multilayer circuit board of a wireless terminal utilizing a UICC, the multilayer circuit board comprising one or more interior layers, the method comprising: manufacturing a multilayer circuit board together with a UICC encapsulated within at least one of the one or more interior layers of the multilayer circuit board, the UICC operatively coupled to the multilayer circuit board; and operatively coupling additional components to the multilayer circuit board, the additional components integral to functionality of the wireless terminal.

In accordance with another aspect of the present technology, there is provided a set of printed circuit assemblies of a wireless terminal, the wireless terminal utilizing a UICC, the set of printed circuit assemblies comprising: a first circuit board comprising a UICC disposed on a first surface thereof; a second circuit board comprising a mating surface configured for mating interconnection with the first surface of the first circuit board, the first surface and the mating surface comprising aligning contacts for facilitating interconnection of the first circuit board with the second circuit board; a cavity formed on one or both of the first circuit board and the second circuit board, the cavity configured to physically accommodate the UICC, thereby facilitating close contact of the first surface and the mating surface for permanent interconnection; and one or more additional components integral to functionality of the wireless terminal, the one or more additional components disposed on one or both of the first circuit board and the second circuit board.

### BRIEF DESCRIPTION OF THE DRAWINGS

These and other features of the technology will become more apparent in the following detailed description in which reference is made to the appended drawings.

FIG. 1 illustrates, in cross section, a multilayer PCB comprising an encapsulated UICC, in accordance with embodiments of the technology.

FIG. 2 illustrates a method of manufacturing a circuit assembly comprising a multilayer PCB and an encapsulated UICC, in accordance with embodiments of the technology.

FIG. 3 illustrates, in cross section, a multilayer circuit board comprising an encapsulated UICC, wherein the multilayer circuit board is an interposer board forming part of a stacked board assembly, in accordance with an embodiment of the present technology.

FIG. 4 illustrates a physical programming interface operatively coupled to the UICC, which is rendered inaccessible after initial programming of the UICC, in accordance with an embodiment of the present technology.

FIG. 5 illustrates a physical programming interface operatively coupled to the UICC, which is rendered inaccessible after initial programming of the UICC, in accordance with another embodiment of the present technology.

FIG. 6 illustrates an unattended M2M wireless terminal, in accordance with an embodiment of the present technology.

FIG. 7 schematically illustrates a wireless terminal having an encryption function provided by the UICC, which is re-used as an encryption function for one or more other operations provided by the wireless terminal, in accordance with an embodiment of the present technology.

### DETAILED DESCRIPTION

As used herein, the term “about” refers to a +/−10% variation from the nominal value. It is to be understood that such a variation is always included in a given value provided herein, whether or not it is specifically referred to.

As used herein, the term “UICC” refers to a Universal Integrated Circuit Card or similar device, or a functional component thereof. The UICC may refer to an entire smart card, one or more associated chips, one or more associated dies, or the like, or a combination thereof. The UICC may contain a Subscriber Identity Module (SIM) application, a Universal Subscriber Identity Module (USIM) application, a Removable User Identity Module (R-UIM), or the like. A UICC is used in mobile terminals in networks such as GSM, UMTS, LTE or the like, for identification and other purposes. Notably, UICCs are generally designed in accordance with a standard which typically intends or allows for them to be removable and interchangeable.

Unless defined otherwise, all technical and scientific terms used herein have the same meaning as commonly understood by one of ordinary skill in the art to which this technology belongs.

An aspect of the present technology provides a multilayer circuit board of a wireless terminal. The wireless terminal is of a type which utilizes a UICC. The multilayer circuit board is configured to accommodate a UICC encapsulated within one or more interior layers of the multilayer circuit board. The completed multilayer circuit board may thus comprise the encapsulated UICC operatively coupled thereto. The multilayer circuit board is further configured to accommodate one or more additional components integral to functionality of the wireless terminal. In various embodiments, the UICC is wholly encapsulated within the circuit board, such that it is fully contained in a cavity that is surrounded on all sides by other circuit board portions.

In various embodiments, the term “multilayer” refers to a PCB having at least an outer layer for disposing circuitry thereon and an inner layer for disposing circuitry thereon. Circuitry may be disposed on one or both of a top and bottom layer of PCB, as well as at least one interior layer. The outer and inner layers may comprise conductive traces, for example. Different layers may be electrically connected using vias, for example. The outer layer may comprise solder pads, lands, plated through holes, or the like, for attaching circuit components such as chips, surface-mount components, through-hole components, or the like. The inner layer may comprise interconnection points such as solder pads, lands, plated through-holes, blind plated through-holes, or the like, which may be used for connection to components to be encapsulated such as the UICC.

The inner layers may further comprise cavities for physically accommodating the components to be encapsulated. Alternatively, once a component is formed on an inner layer, a further layer may be deposited in a fluid manner, for example via a liquid deposition, vapor deposition, spray technique, or the like, which covers and conforms to the surface contours of the encapsulated component. The further layer may then be configured so that, although its surface which is adjacent to the encapsulated component conforms to the contours thereof, its opposite surface is relatively flat.

Accommodating components on a PCB may generally comprise operatively interconnecting the components to each other or to external contacts as necessary. For example, the multilayer PCB may comprise pads, lands, traces, vias, plated through-holes, and the like, to which the various components of the PCB may be connected, thereby both physically and functionally accommodating said components. Components such as semiconductor dies may be accommodated directly by the PCB, for example on a surface layer or interior layer, or provided in a package which is then accommodated by the PCB.

In some embodiments, a semiconductor component of the UICC or for use therewith, may be provided at least partially on an exterior or interior surface of the PCB by directly forming features of the semiconductor component onto the PCB. This may comprise performing semiconductor microfabrication operations directly on the PCB such as lithography (e.g. photolithography), etching, vapor deposition, or the like. Additionally or alternatively, at least some of the encapsulated semiconductor component features may be provided using conventional circuit traces etched onto the PCB. For example, capacitors, inductors, and other circuit elements may be formed by suitably shaped circuit traces. Alternatively, the semiconductor component such as a semiconductor chip or die may be placed onto the PCB and electrically and mechanically coupled thereto using techniques as would be readily understood by a worker skilled in the art.

Another aspect of the present technology provides a circuit assembly of a wireless terminal utilizing a UICC. The circuit assembly comprises a multilayer circuit board generally as described above. The circuit assembly further comprises the encapsulated UICC and the additional components, all operatively coupled to the multilayer circuit board. Additional components on the surface of the multilayer circuit board may be coupled thereto for example by soldering. Components encapsulated within interior layers of the multilayer circuit board may be coupled thereto by techniques as would be readily understood by a worker skilled in the art, for example by placing and soldering the components onto exposed layers of the multilayer circuit board during circuit board assembly, followed by lamination of additional layers onto the multilayer circuit board.

Another aspect of the present technology provides a wireless terminal, such as a mobile device, M2M terminal or module, or the like. The wireless terminal comprises the multilayer circuit board and/or circuit assembly as described above. Further tamper-resistant features may be added to the wireless terminal. An M2M terminal may be a wireless terminal module embedded into automated equipment such as a utility meter, sensor, actuator, traffic light, traffic control or monitoring system, automated remote equipment or monitoring station, or the like. Such M2M terminals are typically unattended and thus subject to theft or tampering.

Another aspect of the present technology provides a method of manufacturing a circuit assembly comprising a multilayer circuit board of a wireless terminal utilizing a UICC. The method comprises manufacturing a multilayer circuit board together with a UICC encapsulated within one or more interior layers of the multilayer circuit board, the UICC operatively coupled to the multilayer circuit board. The method further comprises operatively coupling additional components to the multilayer circuit board. The additional components are integral to functionality of the wireless terminal. Optionally, at least some of the additional components are encapsulated within layers of the multilayer circuit board and manufactured together with the multilayer circuit board.

Another aspect of the present technology provides a set of printed circuit assemblies of a wireless terminal. The wireless terminal utilizes a UICC. The set of printed circuit assemblies includes a first PCB having a UICC disposed on a first surface, optionally at least partially within an open cavity formed on the first PCB's surface. The set of printed circuit assemblies also includes a second PCB comprising a mating surface configured for mating interconnection with the first surface of the first PCB. The first surface and the mating surface comprise aligning contacts, such as solder pads, for facilitating interconnection of the first circuit board with the second circuit board. The interconnection is mechanical and may also be electrical. A cavity is formed on one or both of the first circuit board and the second circuit board, the cavity being configured to physically accommodate the UICC. This allows close contact of the first surface and the mating surface for permanent interconnection. One or more additional components integral to functionality of the wireless terminal are also provided, the one or more additional components disposed on one or both of the first circuit board and the second circuit board, for example on outer surfaces thereof and possibly accommodated by further cavities or the same cavity which accommodates the UICC.

Although the term UICC (Universal Integrated Circuit Card) is used herein, it is intended that this term also cover similar modular identification technology, either present or future. The UICC may correspond to circuitry supporting a SIM application, for example. Furthermore, the UICC need not be a card, e.g. a smart card or small PCB with components thereon, but may be in the form of a semiconductor chip or semiconductor die, or a collection of such semiconductor components and supporting components. In this regard, the term “UICC” as used herein may, where appropriate, be replaced with a term such as “identity circuit” or “modular identity circuit,” which may conform to a proprietary or non-proprietary standard.

Aspects of the present technology comprise a UICC encapsulated between the layers of a PCB that is also the board used as the basis for a complete wireless modem or wireless terminal device. Alternatively, the PCB may be used to accommodate certain critical components of the wireless terminal, while other components may be housed separately. The UICC may be a UICC card, UICC chip, UICC die, or the like. This makes the UICC an integral part of the wireless terminal that is impractical to change. As such, a stolen wireless terminal cannot have its UICC identity used in another wireless terminal and the wireless terminal can only be used with the UICC that is inside it.

Typically, a UICC, such as a smart card carrying a SIM, or the like, is designed to be or at least capable of being modular and transferrable between wireless devices. Thus, the UICC is typically physically removable and often very easily removable. However, contrary to this commonly accepted feature of a UICC, embodiments of the present technology provide specific measures to prevent portability or removability of the UICC. This may provide for theft-deterrence, for example, and more generally may provide measures which mitigate the modularity or portability feature of the UICC which is generally an inherent design feature but which can be exploited by thieves, for example. Therefore, embodiments of the present technology go against the commonly accepted practice of porting UICCs between wireless devices, by making this practice difficult. Furthermore, as opposed to welding or soldering the UICC to the host PCB, the UICC may be integrated with the host PCB at an earlier stage of manufacture and also more securely integrated.

In some embodiments, additional protection of the programmability of the UICC identity is provided to make changing the identity of the UICC more difficult. In some embodiments, such additional protection may be provided at least in part by rendering the physical programming interface to the encapsulated UICC inaccessible after initial programming of the encapsulated UICC. In some embodiments, such additional protection may be provided at least in part via software-based access restriction. In some embodiments, the physical interface to the encapsulated UICC may be made inaccessible after the rest of the wireless device assembled to the circuit board.

In some embodiments, the physical programming interface to the encapsulated UICC may be rendered inaccessible after programming by obscuring the physical programming interface, for example by mounting a component overtop of the physical programming interface after programming, the mounted component being substantially difficult to remove and/or re-attach without damaging same, for example a BGA or fine-pitched component.

In some embodiments, the physical programming interface to the encapsulated UICC may be rendered inaccessible after programming by interrupting one or more conductive links between the interface and the UICC. For example, one or more conductive traces on the PCB between the physical programming interface and the encapsulated UICC can be physically cut after programming. As another example, one or more of the conductive links may comprise a portion, such as a fuse, which can be rendered electrically non-conductive through application of a predetermined amount of voltage or current, or through application of a predetermined amount of heat, ultraviolet radiation, or the like. Such a portion may be embedded within the interior of the PCB to inhibit efforts to re-establish the one or more links. Such a portion may be internal to or external to the UICC.

Aspects of the present technology derive from the realization that it may be undesirably easy to remove and replace the UICC card that is placed in the UICC card holder of prior art wireless terminals. Furthermore, even for a UICC, such as an IC based E-Sim, which is presented as a chip affixed to a main circuit board by soldering, it is possible remove and replace the UICC using standard solder reworking techniques. In both the above cases, the replacement could be done without the owner of the wireless terminal being aware of the change. This opens such configurations up to a higher risk of theft of the wireless terminal, the UICC, or both. For example, a thief may access an unattended M2M terminal, remove its UICC, and sell or repurpose the terminal, the UICC, or both. This can drive up costs such as replacement costs, which in turn limits the locations where M2M terminals can be feasibly used.

In contrast, with a UICC encapsulated into the interior of a PCB which also accommodates components related to other wireless terminal functionality, as described herein, attempts at removing the UICC may be more likely to be physically damaging to the wireless terminal, the UICC, or a combination thereof. This may provide a significant deterrence for problems such as theft. Having the UICC fixed within the PCB may make it difficult to change the identification of a module using such a PCB. It may be much harder than when a UICC is soldered to the surface of a PCB.

In some embodiments, the other components provided on the PCB surface, within the PCB interior, or both, may be low-value components, easily replaceable components, or both.

Encapsulating the UICC into the interior of the PCB may comprise providing components of an integrated circuit die, embodying functionality of the UICC, within one or more interior layers of a multilayer PCB. The UICC die, as it is referred to herein, may be dimensioned having an appropriate size and thickness for inclusion within the PCB interior, and an aperture may be formed within the PCB for accommodating same. The UICC die may be electrically interconnected with the PCB using methods as would be readily understood by a worker skilled in the art.

In some embodiments, different components of the UICC are co-located. In some embodiments, different components of the UICC are provided at different locations and/or layers within the PCB, for example as plural, functionally interconnected integrated circuit dies, thereby making extraction more difficult. In some embodiments, multiple potential sites within the PCB may be defined, and the UICC may be located at one or a subset of the multiple potential sites. During manufacture, the selection of specific sites for location of the UICC may be selected, for example on a board-by-board, batch-by-batch, or revision-by-revision basis. In this way, the location of the UICC in a particular PCB may be further obscured.

In some embodiments, other components of the wireless terminal are accommodated within one or more interior layers of the multilayer PCB. For example, other components critical or integral to functionality of the wireless terminal may be so accommodated, so as to deter theft of the wireless terminal separately from the protected UICC. Such components may include logic components, microprocessors, microcontrollers, amplifiers, analog components, and the like. Some or all such components may be provided on an integrated circuit die to be encapsulated within the PCB interior and interconnected with the PCB.

By providing components encapsulated within the PCB as described herein, some embodiments of the present technology provide for further size and cost reductions for high volume manufactured wireless terminals. Integrated circuit dies on their own do not include their own outer housing or leads, thereby reducing the number of parts of the terminal. Encapsulated components do not protrude from the PCB surface and thus facilitate size reduction.

By providing an embedded UICC as described herein, some embodiments of the present technology provide for uniquely identifiable and customizable wireless terminals in high volume production. Each wireless terminal is provided with a uniquely programmed UICC which is substantially inseparable from the terminal. Encapsulating and programming of the UICC may be performed as part of the manufacturing process, and thereby automated to improve efficiency. Automated programming of the UICC may be followed by automated steps which render the UICC inaccessible to further programming, as described elsewhere herein.

In various embodiments, providing an encapsulated UICC may be performed during or following the multilayer PCB production process in various ways. For example, one or more PCB layers may be formed including an interior layer, at which point the UICC component may be attached to the interior layer, and subsequently further layers of the PCB may be formed overtop of the interior layer and the UICC component. Alternatively the PCB may be formed with an open cavity or an open cavity may be cut within the PCB, the UICC may be placed within the open cavity, and the open cavity may be subsequently covered with further PCB material. Alternatively, two PCB halves may be provided, the UICC may be formed on a surface of one or both PCB halves and the two PCB halves may then be bonded together such that the UICC is interior to the two PCB halves.

By providing an encapsulated UICC as described herein, some embodiments of the present technology provide for wireless terminal products that are more robust and reliable. For example, various embedded components of the wireless terminal may thereby be protected from damage, theft, tampering, and the like. By making components of the wireless terminal product difficult to repurpose, the incentive for theft is reduced.

In some embodiments of the present technology, a UICC is mounted within an interposer board as part of a board stacked assembly. Boards in the board stacked assembly may be adhered to each other, or otherwise permanently or non-permanently connected. The interposer board may contain components, connection routings, or both, which are critical to operation of the board stacked assembly. Other components may be mounted within the board stacked assembly. The board stacked assembly subsequently provides critical functionality of the wireless terminal.

In some embodiments, of the present technology, the encryption within the UICC is re-used for other encryption purposes in the wireless terminal. Encryption functionality is currently provided by a UICC for security purposes. By re-using this encryption functionality for other processes run by the wireless terminal, the UICC becomes substantially indispensable in said other operations. Thus, removing the UICC may render the remainder of the wireless terminal inoperative, thus deterring theft and/or tampering. In some embodiments, the other processes run by the wireless terminal are processes that pre-specify encryption is required, and the UICC-provided encryption is provided as said encryption. In some embodiments, the other processes run by the wireless terminal are modified to require encryption, which is then provided by the UICC.

In some embodiments, the UICC may be integrated into other operations in other ways. For example the UICC may be configured to store data in memory thereof which is critical for said other operations of the wireless terminal. As another example the UICC may be configured to pass signals, for example from one terminal to another, and thus become part of the wireless terminal circuitry. Other functionalities of the UICC may be similarly integrated into the wireless terminal for supporting its function, even if these functionalities could have been more simply provided without use of the UICC. Such measures may deter theft of the wireless terminal since the UICC cannot easily be removed and replaced without disrupting functionality of the wireless terminal. Such measures may also deter theft of the UICC since the UICC may be programmed to provide extraneous signals when used with a different wireless terminal, which would disrupt operation.

In some embodiments, test and self-test features are included in the encapsulated UICC or other circuits or both to enable testability. This may reduce or eliminate physical access requirements to the UICC, thereby increasing security and/or removing the need to initially provide and then render inaccessible physical access to the UICC.

In some embodiments, components embedded into the PCB comprise near field communications devices, microcontrollers, energy harvesting devices, solid state batteries and memory. Such encapsulating may deter theft of these components individually. Such encapsulating may additionally or alternatively deter theft of some or the entire wireless terminal by separating plural components thereof from the PCB and transplanting them to a new, equivalent PCB which also accommodates a new UICC.

In some embodiments, RF shielding layers are provided within the PCB, for example as required to shield components encapsulated within or otherwise attached to the PCB. RF shielding layers may be provided as areas of conductive material within or on the surface of a multilayer PCB, for example.

The technology will now be described with reference to specific examples. It will be understood that the following examples are intended to describe embodiments of the technology and are not intended to limit the technology in any way.

### EXAMPLES

### Example 1

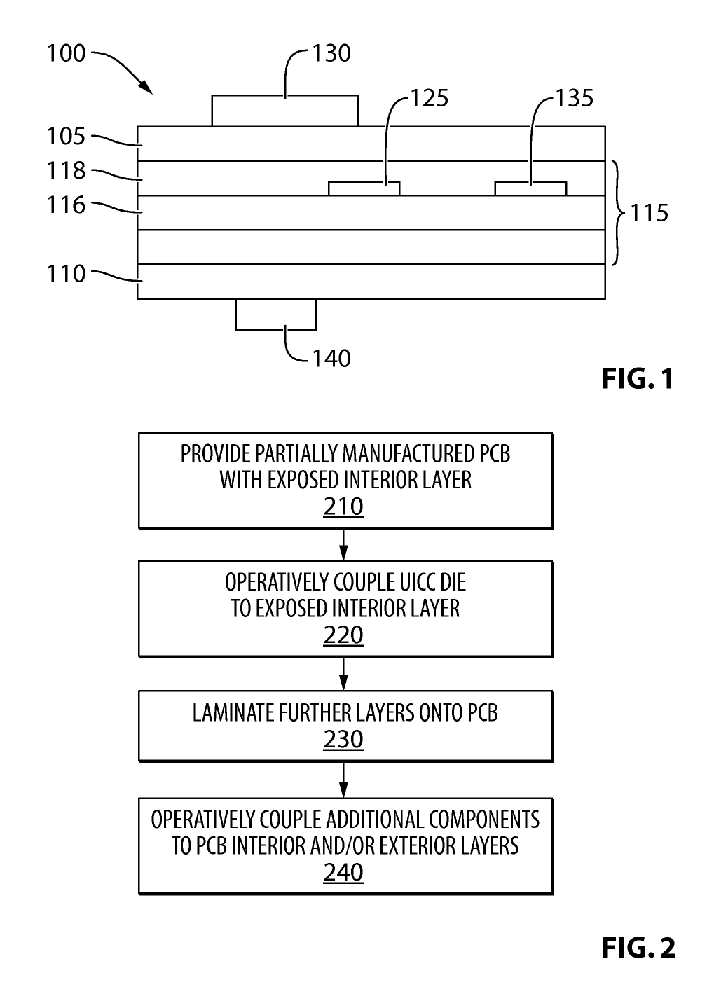

FIG. 1 illustrates a cross-sectional side view of a PCB 100 comprising two exterior layers 105 and 110, and at least one interior layer 115. Dimensions of FIG. 1 are exaggerated for clarity. The PCB 100 is made to be a component of a wireless terminal (not shown), which accommodates the UICC as well as at least one other electronic component providing a function of the wireless terminal, such as digital signal processing, digital logic, data storage, analog amplification, power management, modulation, radio transmission, radio reception, machine or user interface, and the like, as would be readily understood by a worker skilled in the art. In one embodiment, the PCB may accommodate components associated with substantially all or at least a significant portion of functions of the wireless terminal.

The interior layer 115 comprises a UICC die 125, for example provided within an aperture within the interior layer. The interior layer 115 comprises a layer 116 onto which conductive traces are formed, as well as an adjacent insulating layer 118. Thus, during manufacture, the UICC die 125 may be placed on top of and operatively coupled to the layer 116, and subsequently the insulating layer 118 may be formed overtop of the layer 116 and the UICC die. Further layers such as the exterior layer 105 may be provided subsequently by lamination. Other configurations for providing a semiconductor die within an interior layer may also be used, as would be readily understood by a worker skilled in the art.

Other electronic components are also accommodated by the PCB 100, for example an electronic chip 130 soldered to the exterior layer 105, an electronic chip 140 soldered to the exterior layer 110, and optionally a semiconductor die 135 accommodated within the interior layer 115 or optionally another interior layer. These and other electronic components provide various other functions of the wireless terminal, and may be integrated together and with the UICC.

### Example 2

FIG. 2 illustrates a method of manufacturing a circuit assembly comprising a multilayer PCB and an encapsulated UICC, in accordance with embodiments of the present technology. As illustrated, the method comprises providing 210 a partially manufactured PCB with an exposed interior layer; operatively coupling 220 a UICC die to the exposed interior layer; laminating 230 further layers onto the PCB; and operatively coupling 240 additional components to PCB interior and/or exterior layers. Various operations involved with each step may be performed in a manner as would be readily understood by a worker skilled in the art. Operative coupling of additional components such as semiconductor dies to interior layers of the PCB may be performed during manufacture of the PCB, when the appropriate interior layer is exposed and before further layers are added.

### Example 3

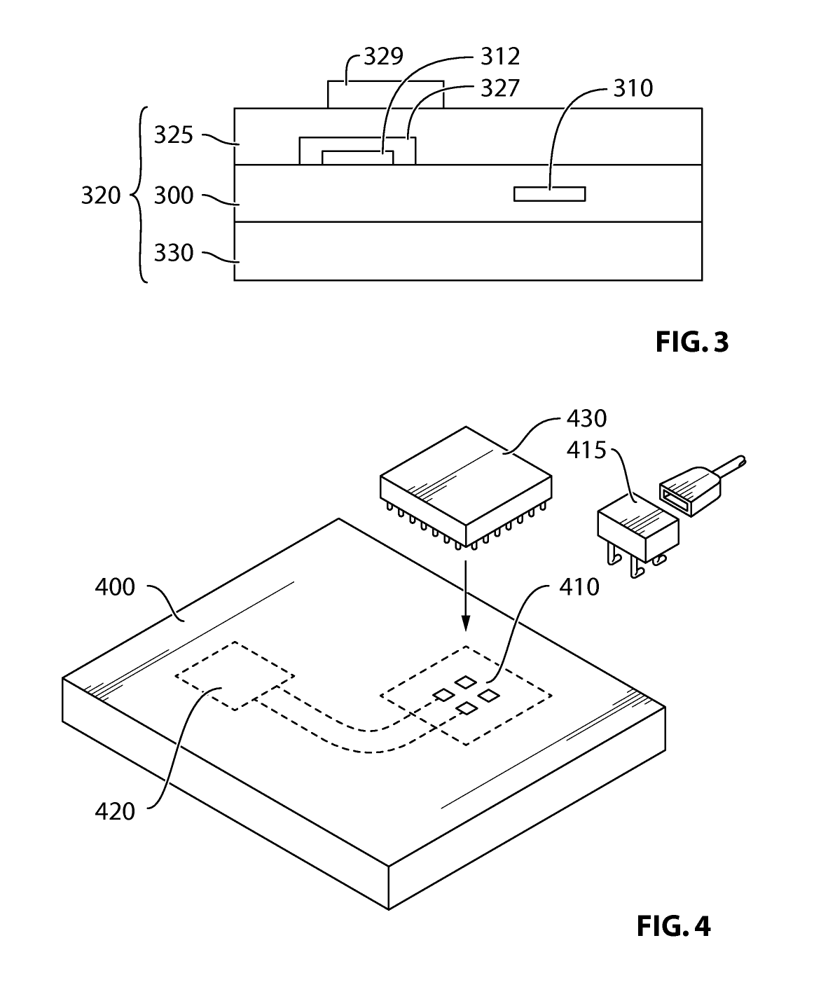

FIG. 3 illustrates a cross-sectional side view of a multilayer circuit board 300 comprising an encapsulated UICC 310, along with adjacent circuit boards 325, 330, in accordance with an embodiment of the present technology. The multilayer circuit board 300 is an interposer board forming part of a stacked board assembly 320. The stacked board assembly 320 comprises one or more additional PCBs, such as PCBs 325 and 330. The PCBs 300, 325 and 330 are mechanically and electrically interconnected, for example using adhesive, mating connectors, solder, or the like, or a combination thereof. Each of the PCBs 300, 325 and 330 may comprise mating connectors, solder pads, or the like, on the surfaces thereof for interconnection. Additionally, the PCBs 325 and 330 need not be multilayer circuit boards having an interior layer, but may comprise and/or be populated only on a top layer, only on a bottom layer or only on top and bottom layers.

It is also contemplated that the UICC 310 may be located on a top or bottom surface of the PCB 300, and a cavity may be formed in either or both of the PCB 300 and the PCB 325 or 330 which is adjacent to the UICC so located. Thus, the UICC is encapsulated by the stacked combination of the PCBs once the PCBs are interconnected. This approach is similar to encapsulating the UICC within a PCB, except that each PCB is viewed as a layer, and the encapsulating PCB is replaced with an encapsulating stack of PCBs. One or more of the PCBs 300, 325 and 330 may then further comprise one or more additional components, for example component 329, integral to functionality of the wireless terminal.

Various other features of the stack of PCBs may be provided, similarly to the various other features of a single encapsulating PCB as described elsewhere herein. In some embodiments, only two of the PCBs 300, 325 and 330 are provided, with the UICC disposed between the two PCBs and electrically connected to a surface of one or both of the PCBs. For example the UICC may be disposed at location 312 instead of (or in addition to) the location 310. The location 312 surrounded by a cavity 327 in the PCB 325, as an example. Furthermore, if the UICC is disposed on a surface of the PCB 300, this PCB need not be a multilayer circuit board, as the UICC is disposed on the surface and an interior layer may not be required.

### Example 4

FIG. 4 illustrates a physical programming interface 410 provided on a PCB 400, in accordance with an embodiment of the present technology. The interface 410 is operatively coupled to a UICC 420 provided in the interior of the PCB 400. As illustrated, the interface 410 is rendered inaccessible after initial programming of the UICC by affixing a component 430 overtop of the interface. A temporary connector 415 may also optionally be attached to the interface 410 and subsequently removed as part of rendering the interface inaccessible. Other means of rendering the component inaccessible, such as shorting contacts of the interface, open-circuiting circuit traces, or the like, may also be employed. The interface 410 may comprise through-holes or solder pads for receiving corresponding pins or leads of the temporary connector 415. The interface 410 may further comprise through-holes or pads (not shown) for operatively connecting the component 430.

### Example 5

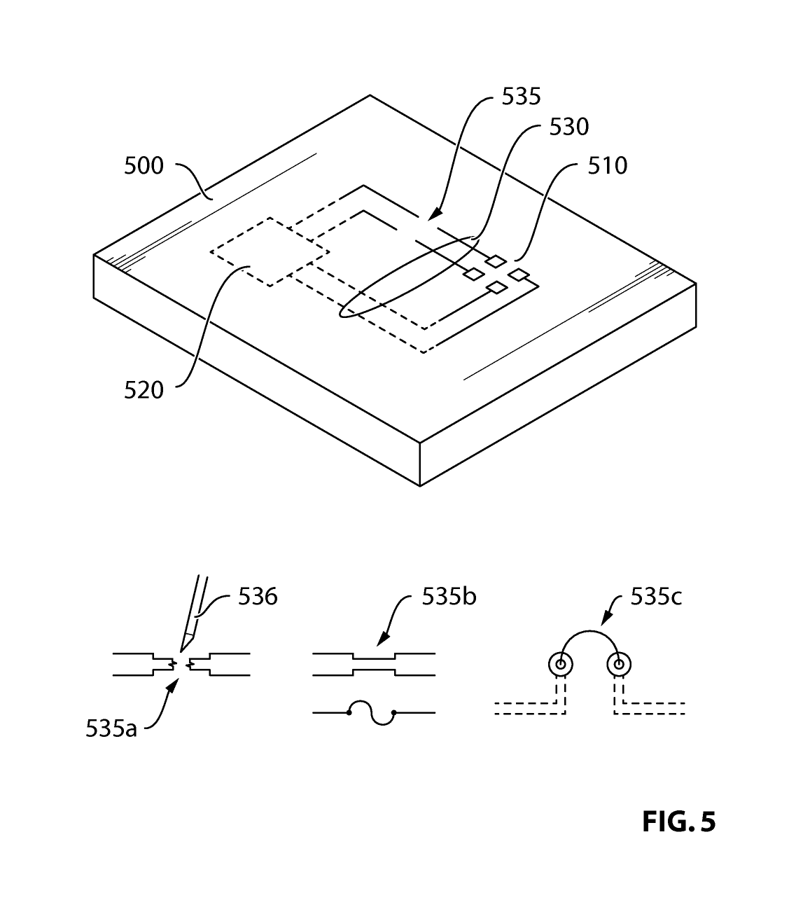

FIG. 5 illustrates a physical programming interface 510 provided on a PCB 500, in accordance with an embodiment of the present technology. The interface 510 is operatively coupled to a UICC 520 provided in the interior of the PCB 500. As illustrated, the interface 510 is coupled to the UICC via breakable conductors 530, and the interface is decoupled from the UICC after initial programming of the UICC by opening the breakable conductors 530 at location 535. As the location 535 is on the PCB surface, it may be mechanically broken by physically cutting or ablating the conductors. As an example, a breakable conductor 535a is illustrated with a corresponding tool 536 which has been used to cut the conductor 535a.

Alternatively, the location 535 may comprise a fuse-like portion, such as a thin conductive trace made of a predetermined material such as zinc, copper, silver, aluminum, or alloy, or a semiconductor fuse material such as used in legacy field programmable gate arrays (FPGA). The fuse-like portion is configured to open-circuit in response to a relatively high-current pulse or other stimulus which is applied following programming of the UICC. Means such as a cavity formed around the fuse may be provided for accommodating the fuse action without damaging the remainder of the PCB. In this case the location 535 may optionally be on an interior layer of the PCB, which may improve security since the fuse is inaccessible for re-completing the circuit. As an example, a fuse 535b is illustrated which may be disposed on an interior layer of the PCB.

Alternatively, the PCB may be manufactured such that the conductors 530 are initially open-circuited, and the circuit may be temporarily completed during programming, for example by installing solder, jumper wires, or the like. Vias may be provided for accommodating the jumper wires, for example. Again in this case the conductors may optionally be located substantially entirely on an interior layer of the PCB. As an example, a jumper 535c is illustrated which is temporarily used to join two vias for completing the circuit 535.

### Example 6

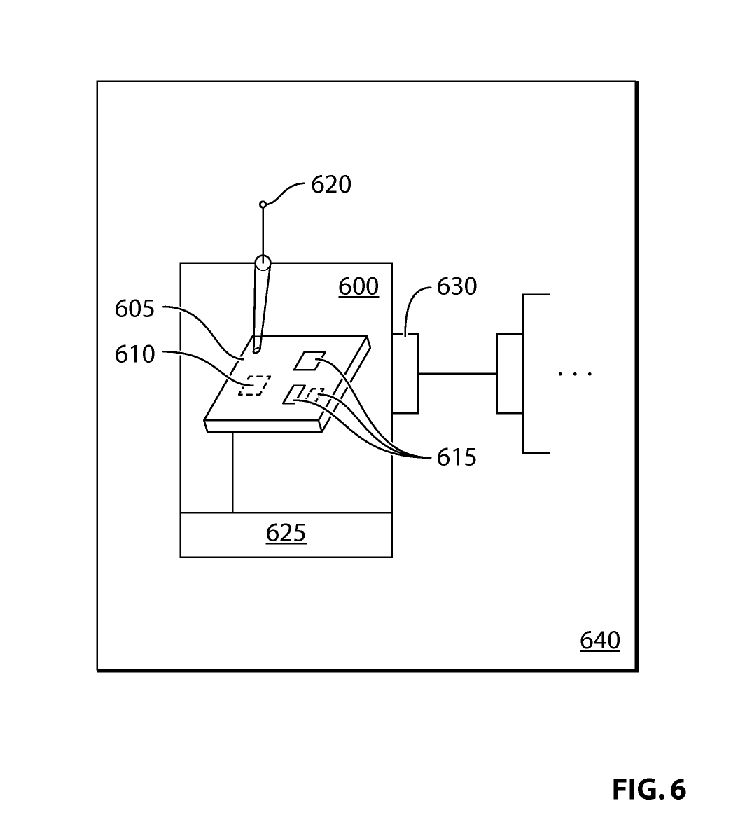

FIG. 6 illustrates an unattended M2M wireless terminal 600, in accordance with an embodiment of the present technology. The M2M wireless terminal 600 comprises a circuit assembly, which comprises a multilayer circuit board 605. The multilayer circuit board 605 comprises a UICC 610 encapsulated within at least one of the one or more interior layers of the multilayer circuit board. The circuit assembly comprises additional components 615 accommodated by the multilayer circuit board 605 and integral to functionality of the wireless terminal. The M2M wireless terminal 600 further comprises an external antenna 620, power source 625, and interface module 630. The interface module 630 is provided for interfacing the M2M wireless terminal 600 with associated equipment 640 such as a utility meter, sensor, actuator, traffic light, traffic control or monitoring system, automated remote equipment or monitoring station, or the like.

### Example 7

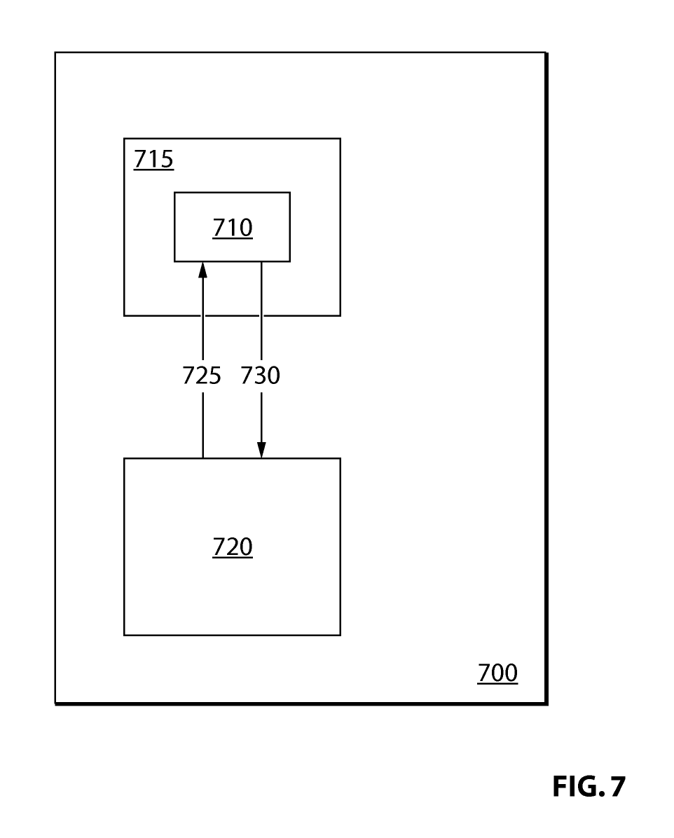

FIG. 7 illustrates a block diagram of portions of a wireless terminal 700, in accordance with an embodiment of the present technology. The wireless terminal 700 has an encryption function 710 provided by the UICC 715. The encryption function 710 is re-used as an encryption function for at least one other operation or function 720 provided by the wireless terminal.

As illustrated, the function 720 may provide data 725 to the UICC 715 and hence to the encryption function 710, the data 725 to be encrypted or decrypted. An outcome 730 of the encryption or decryption operation is provided as data back to the function 720. The function 720 may be associated with a single electronics module external to the UICC 715 or plural electronics modules.

In accordance with some embodiments of the present technology, the encryption may be used for electronic payment verification as is done with credit and debit cards. In some embodiments, the encryption may be used for secure message transmission and reception.

It is obvious that the foregoing embodiments of the technology are examples and can be varied in many ways. Such present or future variations are not to be regarded as a departure from the spirit and scope of the technology, and all such modifications as would be obvious to one skilled in the art are intended to be included within the scope of the following claims.

1. A multilayer circuit board of a wireless terminal, the wireless terminal utilizing a UICC, the multilayer circuit board comprising one or more interior layers and configured to accommodate:
a.) a UICC encapsulated within at least one of the one or more interior layers of the multilayer circuit board; and
b.) one or more additional components integral to functionality of the wireless terminal.

2. The multilayer circuit board according to claim 1, wherein at least one of the one or more additional components is encapsulated within at least one of the one or more interior layers of the multilayer circuit board.

3. The multilayer circuit board according to claim 1, wherein the UICC is provided as one or more integrated circuit dies.

4. The multilayer circuit board according to claim 1, wherein the multilayer circuit board is an interposer board forming part of a stacked board assembly.

5. The multilayer circuit board according to claim 1, wherein the UICC is electrically coupled via one or more electrical channels to one or more contacts on a surface of the multilayer circuit board, and wherein said electrical channels are interior to the multilayer circuit board and comprise fuses which can be open-circuited.

6. The multilayer circuit board according to claim 1, wherein the multilayer circuit board comprises circuit traces, circuit attachment points, or an internal component, located adjacent to the UICC and on or underneath a surface of the multilayer circuit board.

7. A circuit assembly of a wireless terminal utilizing a UICC, the circuit assembly comprising a multilayer circuit board as described in claim 1, the circuit assembly further comprising the UICC and the additional components operatively coupled to the multilayer circuit board.

8. The circuit assembly according to claim 7, wherein a physical programming interface operatively coupled to the UICC is rendered inaccessible after initial programming of the UICC.

9. The circuit assembly according to claim 7, wherein a physical programming interface operatively coupled to the UICC is decoupled from the UICC after initial programming of the UICC.

10. The circuit assembly according to claim 7, wherein the additional components comprise one or more components selected from the group comprising: near field communications devices, microcontrollers, energy harvesting devices, solid state batteries and memory.

11. A wireless terminal comprising the multilayer circuit board as described in claim 1.

12. The wireless terminal according to claim 11, wherein the wireless terminal is an unattended M2M terminal.

13. The wireless terminal according to claim 11, wherein an encryption function provided by the UICC is re-used as an encryption function for one or more other operations provided by the wireless terminal.

14. A set of printed circuit assemblies of a wireless terminal, the wireless terminal utilizing a UICC, the set of printed circuit assemblies comprising:
a.) a first circuit board comprising a UICC disposed on a first surface thereof;
b.) a second circuit board comprising a mating surface configured for mating interconnection with the first surface of the first circuit board, the first surface and the mating surface comprising aligning contacts for facilitating interconnection of the first circuit board with the second circuit board;
c.) a cavity formed on one or both of the first circuit board and the second circuit board, the cavity configured to physically accommodate the UICC, thereby facilitating close contact of the first surface and the mating surface for permanent interconnection; and
d.) one or more additional components integral to functionality of the wireless terminal, the one or more additional components disposed on one or both of the first circuit board and the second circuit board.

15. The set of printed circuit assemblies according to claim 14, wherein at least one of the one or more additional components is encapsulated within the cavity.

16. The set of printed circuit assemblies according to claim 14, wherein the UICC is provided as one or more integrated circuit dies.

17. The set of printed circuit assemblies according to claim 14, wherein the UICC is electrically coupled via one or more electrical channels to one or more contacts on a surface of the first circuit board, and wherein said electrical channels are interior to the first circuit board and comprise fuses which can be open-circuited.

18. The set of printed circuit assemblies according to claim 14, comprising circuit traces, circuit attachment points, or an internal component, located adjacent to the UICC in the cavity.
